(19) United States
(12) Patent Application Publication
(10) Pub. No.: US 2025/0006720 A1
(43) Pub. Date: Jan. 2, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Daeyoung JUNG, Suwon-si (KR); Jongbo SHIM, Suwon-si (KR)

(73) Assignee: Samsung Electronics Co., Ltd., Suwon-si (KR)

(21) Appl. No.: 18/631,555

(22) Filed: Apr. 10, 2024

(30) Foreign Application Priority Data
Jun. 28, 2023 (KR) 10-2023-0083310

(51) Int. Cl. H01L 25/18; H01L 21/56; H01L 23/00; H01L 23/29; H01L 23/31; H01L 23/498

(52) U.S. Cl. CPC H01L 25/18; H01L 21/565; H01L 23/293; H01L 23/3128; H01L 23/49838; H01L 23/49894; H01L 24/16; H01L 24/32; H01L 24/48; H01L 24/73; H01L 24/85; H01L 21/563; H01L 24/06; H01L 24/49; H01L 2224/06151; H01L 2224/06155; H01L 2224/16227; H01L 2224/32145; H01L 2224/32225; H01L 2224/48227; H01L 2224/48997; H01L 2224/49175; H01L 2224/73204; H01L 2224/73253; H01L 2224/73265; H01L 2224/85007; H01L 2924/3862

(57) ABSTRACT

A semiconductor package includes a package substrate, at least one dam structure extending on the package substrate to surround substrate pads and defining an inner space that accommodates the substrate pads on the package substrate, a first semiconductor on the package substrate, a second semiconductor chip attached to the first semiconductor chip by an adhesive film, bonding wires electrically connecting chip pads of the second semiconductor chip to the substrate pads of the package substrate, a first underfill member filling a gap between the package substrate and the first semiconductor chip, a second underfill member filling the inner space of the at least one dam structure, and a molding member covering the first semiconductor chip, the second semiconductor chip and the first and second underfill members on the package substrate.

### PRIORITY STATEMENT

This application claims priority under 35 U.S.C. § 119 to Korean Patent Application No. 10-2023-0083310, filed on Jun. 28, 2023 in the Korean Intellectual Property Office (KIPO), the contents of which are herein incorporated by reference in their entirety.

### BACKGROUND

### 1. Field

The present disclosure relates to semiconductor packages and methods of manufacturing the semiconductor packages. More particularly, the present disclosure relates to semiconductor packages including a plurality of different semiconductor chips stacked on a package substrate and methods of manufacturing the same.

### 2. Description of the Related Art

In a Hybrid System In Package, a lower semiconductor chip may be mounted on a package substrate using a flip chip method, and an upper semiconductor chip may be attached on the lower semiconductor chip using an adhesive film such as a die attach film (DAF) and mounted using a wire bonding method. During a molding process, a bonding wire may be torn from a bond finger due to a wire sweeping failure due to heat and pressure of epoxy mold compound (EMC), resulting in poor reliability. Also, since the wire bonding process is performed after an underfill process under the lower semiconductor chip, a surface of the bond finger may be contaminated by fumes from an underfill solution in the underfill process, which may cause defects during the wire bonding process.

### SUMMARY

Example embodiments of the inventive concepts provide a semiconductor package capable of preventing sweep of bonding wires during a molding process and having improved reliability.

Example embodiments of the inventive concepts provide a method of manufacturing the semiconductor package.

Embodiments of the inventive concepts provide a semiconductor package that includes a package substrate having an upper surface and a lower surface opposite the upper surface, the package substrate including a first region and a second region surrounding the first region, the package substrate including first substrate pads on the upper surface in the first region and second substrate pads on the upper surface in the second region; at least one dam structure protruding from the upper surface of the package substrate and having a first height from the upper surface of the package substrate, the at least one dam structure extending to surround the second substrate pads and defining an inner space that accommodates the second substrate pads on the package substrate; a first semiconductor chip disposed in the first region on the package substrate such that a first surface on which first chip pads are formed faces the package substrate; a second semiconductor chip attached to a second surface of the first semiconductor chip opposite to the first surface by an adhesive film, the second semiconductor chip having a third surface and a fourth surface opposite to the third surface, the fourth surface having second chip pads thereon, and the third surface facing the first semiconductor chip; bonding wires electrically connecting the second chip pads of the second semiconductor chip to the second substrate pads of the package substrate; a first underfill member filling a gap between the first semiconductor chip and the upper surface of the package substrate; a second underfill member at least partially filling the inner space of the at least one dam structure; and a molding member covering the first semiconductor chip, the second semiconductor chip, and the first and second underfill members on the package substrate.

Embodiments of the inventive concepts further provide a semiconductor package that includes a package substrate including a first region and a second region surrounding the first region, the package substrate having first substrate pads in the first region and second substrate pads in the second region along at least one side portion of the package substrate; at least one dam structure extending to surround the second substrate pads on an upper surface of the package substrate and defining an inner space that accommodates the second substrate pads on the upper surface of the package substrate; a first semiconductor chip in the first region of the package substrate and mounted on the first substrate pads via conductive bumps that are on first chip pads of the first semiconductor chip; a second semiconductor chip on the first semiconductor chip, the second semiconductor chip having a backside surface and a front surface opposite the backside surface, the front surface having second chip pads thereon, and the backside surface faces the first semiconductor chip; bonding wires electrically connecting the second chip pads of the second semiconductor chip to the second substrate pads of the package substrate; a first underfill member filling a gap between the first semiconductor chip and the package substrate; a second underfill member filling the inner space of the at least one dam structure, the second underfill member provided on the second substrate pads; and a molding member covering the first semiconductor chip, the second semiconductor chip, and the first and second underfill members on the package substrate.

Embodiments of the inventive concepts still further provide a semiconductor package that includes a package substrate including a first region and a second region surrounding the first region, the package substrate having first substrate pads in the first region and second substrate pads in the second region along at least one side portion of the package substrate; at least one dam structure protruding from the upper surface of the package substrate at having a first height from the package substrate, the at least one dam structure extending to surround the second substrate pads and defining an inner space that accommodates the second substrate pads on the package substrate; a first semiconductor chip in the first region of the package substrate, the first semiconductor chip having a first surface with first chip pads thereon, the first surface facing the package substrate, the first semiconductor chip mounted on the first substrate pads via conductive bumps on the first chip pads; a second semiconductor chip on a second surface of the first semiconductor chip opposite to the first surface by an adhesive film, the second semiconductor chip exposing a portion of the second surface of the first semiconductor chip, the second semiconductor chip having a fourth surface opposite to a third surface, the fourth surface having second chip pads thereon, and the third surface facing the first semiconductor chip; bonding wires electrically connecting the second chip pads of the second semiconductor chip to the second substrate pads of the package substrate; a first underfill member filling a gap between the first semiconductor chip and the package substrate; a second underfill member filling the inner space of the at least one dam structure and on the second substrate pads; and a molding member covering the first semiconductor chip, the second semiconductor chip, and the first and second underfill members on the package substrate. The first height of the at least one dam structure is within a range of 10 um to 30 um.

Embodiments of the inventive concepts further provide a method of manufacturing a semiconductor package that includes providing a package substrate having first substrate pads disposed in a first region and second substrate pads disposed in a second region that surrounds the first region. At least one dam structure is formed on the package substrate to extend and to surround the second substrate pads, and to define an inner space that accommodates the second substrate pads on the package substrate. A first semiconductor chip is mounted in the first region of the package substrate via conductive bumps that are formed on first chip pads of the first semiconductor chip. A second semiconductor chip is disposed on the first semiconductor chip, the second semiconductor chip having a backside surface opposite to a front surface, the front surface having second chip pads formed thereon, and the backside surface faces the first semiconductor chip. The second chip pads of the second semiconductor chip are electrically connected to the second substrate pads of the package substrate by bonding wires. A first underfill member is formed to fill a gap between the first semiconductor chip and the package substrate. A second underfill member is formed to fill the inner space of the at least one dam structure and to be provided on the second substrate pads. A molding member is formed on the package substrate to cover the first semiconductor chip, the second semiconductor chip, and the first and second underfill members.

According to example embodiments, a semiconductor package may include at least one dam structure extending on a package substrate to surround substrate pads and defining an inner space that accommodates the substrate pads on the package substrate, a first semiconductor chip on the package substrate, a second semiconductor chip attached to the first semiconductor chip by an adhesive film, bonding wires electrically connecting chip pads of the second semiconductor chip to the substrate pads of the package substrate, a first underfill member filling a gap between the package substrate and the first semiconductor chip, a second underfill member filling the inner space of the at least one dam structure, and a molding member covering the first semiconductor chip, the second semiconductor chip and the first and second underfill members on the package substrate.

Since the second underfill member covers end portions of the bonding wires that are bonded to the substrate pads and surfaces of the substrate pads exposed by the end portions of the bonding wires, when forming the molding member by a molding process using a transfer mold, wire sweeping defects of the bonding wires may be limited or prevented to thereby improve mechanical and electrical reliability of the semiconductor package.

Further, since a process of forming the first underfill member is performed after the bonding wire process of the bonding wires, the surfaces of the second substrate pads may be limited or prevented from being contaminated by fumes of an underfill solution in the process of forming the first underfill member. Accordingly, defects occurring during the wire bonding process due to the contamination of the surface of the bond finger may be limited or prevented.

### BRIEF DESCRIPTION OF THE DRAWINGS

Example embodiments will be more clearly understood from the following detailed description taken in conjunction with the accompanying drawings. FIGS. 1 to 14 represent non-limiting, example embodiments as described herein.

FIG. 1 is a cross-sectional view illustrating a semiconductor package in accordance with some example embodiments of the inventive concepts.

FIG. 2 is a plan view of FIG. 1.

FIG. 3 is an enlarged cross-sectional view illustrating portion ‘A’ in FIG. 1.

FIGS. 4, 5, 6, 7, 8, 9, 10, 11, 12, 13 and 14 are views illustrating a method of manufacturing a semiconductor package in accordance with some example embodiments of the inventive concepts.

### DETAILED DESCRIPTION

Hereinafter, example embodiments will be explained in detail with reference to the accompanying drawings. In all figures in this specification, directions indicated by an arrow and a reverse direction thereto are considered as the same direction.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

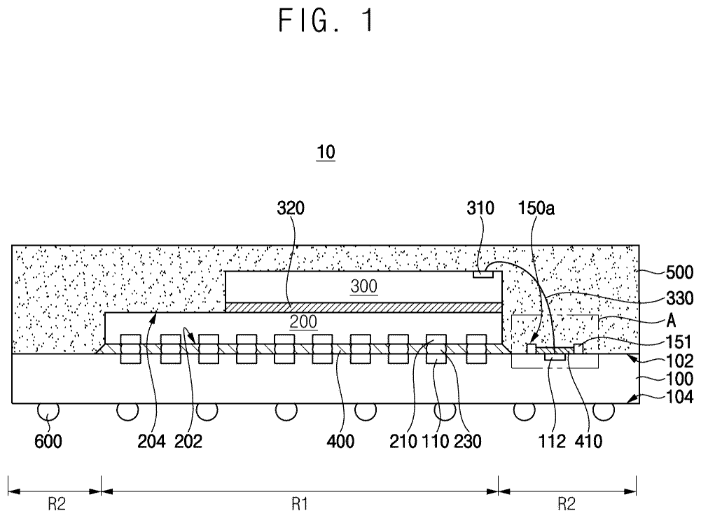

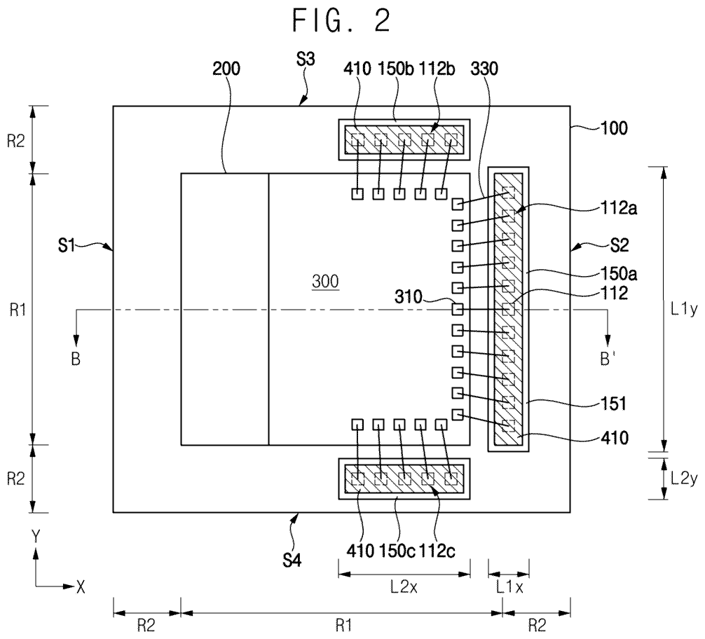

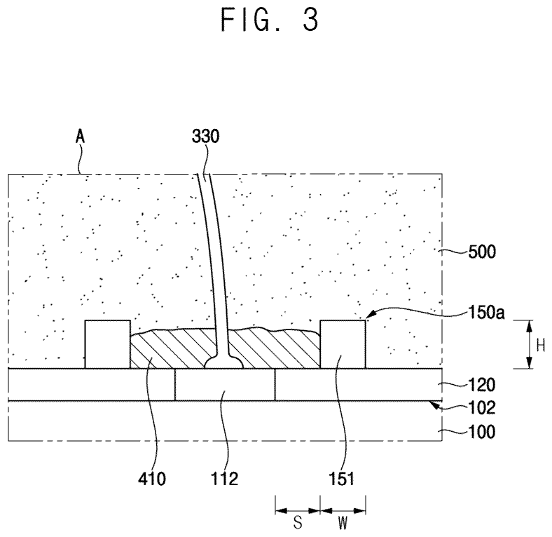

FIG. 1 is a cross-sectional view illustrating a semiconductor package in accordance with some example embodiments. FIG. 2 is a plan view of FIG. 1. FIG. 3 is an enlarged cross-sectional view illustrating portion ‘A’ in FIG. 1. FIG. 1 is a cross-sectional view taken along the line B-B′in FIG. 2. FIG. 2 is a plan view illustrating the semiconductor package in FIG. 1, wherein a molding member is omitted.

Referring to FIGS. 1 to 3, a semiconductor package 10 may include a package substrate 100 having first substrate pads 110 and second substrate pads 112, at least one dam structure extending to surround the second substrate pads 112 of the package substrate 100, a first semiconductor chip 200 disposed on the package substrate 100, a second semiconductor chip 300 disposed on an upper surface of the first semiconductor chip 200, first conductive connection members 230 electrically connecting the first semiconductor chip 200 to the first substrate pads 110 of the package substrate 100, bonding wires 330 as second conductive connection members electrically connecting to the second substrate pads 112 of the package substrate 100, a first underfill member 400 filling a gap between the package substrate 100 and the first semiconductor chip 200, a second underfill member 410 at least partially filling an inner space of the at least one dam structure, and a molding member 500 covering the first semiconductor chip 200, the second semiconductor chip 300 and the first and second underfill members 400 and 410 on the package substrate 100. The semiconductor package 10 may further include external connection members 600.

The semiconductor package 100 may be a multi-chip package (MCP) including semiconductor chips of the same or different types. The semiconductor package 100 may be a System In Package (SIP) including a plurality of semiconductor chips stacked or variously arranged in a single package, but being capable of performing a multiplicity of functions associated with an electronic system. For example, the semiconductor package 100 may be a modem system-in-package having a modem for mobile phone communication.

In some example embodiments, the package substrate 100 may be a substrate having an upper surface 102 and a lower surface 104 opposite to each other. For example, the package substrate 100 may include a printed circuit board (PCB), a flexible substrate, a tape substrate, etc. The printed circuit board may be a multilayer circuit board having vias and various circuits therein. The package substrate 100 may include internal wirings for electrical connection between the first semiconductor chip 200 and the second semiconductor chip 300.

The package substrate 100 may include a first side portion S1 and a second side portion S2 extending in a direction perpendicular to the upper surface 102 and parallel to a second direction (Y direction) and facing each other. The package substrate 100 may further include a third side portion S3 and a fourth side portion S4 extending in a direction parallel to a first direction (X direction) and perpendicular to the second direction and facing each other.

The package substrate 100 may include a first region R1 and a second region R2 surrounding the first region R1. The first region R1 may be a chip mounting region on which the first semiconductor chip 200 and the second semiconductor chip 300 are mounted. The second region R2 may be a peripheral region surrounding the chip mounting region. The first region R1 may have a rectangular shape.

The package substrate 100 may include the first substrate pads 110 for electrical connection with the first semiconductor chip 200 and the second substrate pads 112 for electrical connection with the second semiconductor chip 300. The first substrate pads 110 may be provided in the first region R1 on the upper surface 102 of the package substrate 100 and may be electrically connected to the first semiconductor chip 200. The first substrate pads 110 may be arranged in an array form within the first region R1. The second substrate pads 112 may be provided in second region R2 on the upper surface 102 of the package substrate 100 and may be electrically connected to the second semiconductor chip 300.

The second substrate pads 112 may be arranged to be spaced apart from each other along the second, third and fourth side portions S2, S3 and S4. The second substrate pads 112 may include a first group of pads 112a arranged along the second side portion S2 of the package substrate 100, a second group of pads 112b arranged along the third side portion S3 of the package substrate 100, and a third group of pads 112c arranged along the fourth side portion S4 of the package substrate 100.

The first and second substrate pads 110 and 112 may be respectively connected to the wirings (e.g., the internal wirings of the package substrate 100). The wirings may extend on the upper surface 102 or inside the package substrate 100. For example, at least a portion of the wirings may be used as a landing pad or as a substrate pad.

Although only some substrate pads are illustrated in the figures, it will be understood that the number, shape, and arrangement of the substrate pads are provided as examples, and the inventive concepts are not limited thereto. Further description and illustration of the wirings as well as the substrate pads to which the inventive concepts pertain will be omitted from the following.

A first insulating layer 120 may be formed on the upper surface 102 of the package substrate 100 to expose the first and second substrate pads 110 and 112. The first insulating layer 120 may cover the entire upper surface 102 of the package substrate 100 excluding the first and second substrate pads 110 and 112. For example, the first insulating layer may include solder resist.

In some example embodiments, the at least one dam structure may be provided in the second region R2 on the upper surface 102 of the package substrate 100 to surround the second substrate pads 112. The dam structure may protrude from the upper surface 102 of the package substrate 110 to have a desired (and/or alternatively predetermined) height H (e.g., a first height). The dam structure may include a barrier 151 that extends to surround the second substrate pads 112.

For example, the barrier 151 of the dam structure may be formed by forming a protective layer such as a solder resist on the first insulating layer 120 and performing an exposure process and a development process on the protective layer.

As illustrated in FIG. 3, the height H of the barrier 151 of the at least one dam structure may be within a range of about 10 μm to 30 μm. A width W of the barrier 151 of the at least one dam structure may be within a range of about 100 μm to 200 μm. A gap S between an inner wall of the barrier 151 of the at least one dam structure and the second substrate pad 112 may be within a range of about 100 μm to 250 μm.

The at least one dam structure may include a first dam structure 150a surrounding the first group of pads 112a, a second dam structure 150b surrounding the second group of pads 112b, and a third dam structure 150c surrounding the third group of pads 112c. A length L1x of the first dam structure 150a in the first direction (X direction) may be within a range of about 100 μm to 250 μm, and a length L1y of the first dam structure 150a in the second direction (Y direction) may be within a range of about 4,000 μm to 5,000 μm. A length L2x of the third dam structure 150c in the first direction (X direction) may be within a range of about 2,000 μm to 3,000 μm, and a length L2y of the third dam structure 150c in the second direction (Y direction) may be within a range of about 200 μm to 300 μm.

In some example embodiments, the first semiconductor chip 200 may be mounted in the first region R1 of the package substrate 100. The first semiconductor chip 200 may be mounted in the first region R1 on the upper surface 102 of the package substrate 100 via conductive bumps 230 as the first conductive connection members. The first semiconductor chip 200 may be disposed such that a front surface 202 on which first chip pads 210 are formed, that is, an active surface, faces the package substrate 100. The first semiconductor chip 200 may have a rectangular shape with four sides when viewed from plan view. The first chip pads 210 may be arranged in an array over the entire front surface 202 of the first semiconductor chip 200 corresponding to the first substrate pads 110.

The first semiconductor chip 200 may be a logic chip including a logic circuit. The logic chip may be a controller that controls memory chips. The first semiconductor chip may be a processor chip such as ASIC, an application processor AP, etc. serving as a host such as a CPU, GPU, or SOC. The first semiconductor chip may include a central processing unit (CPU), a graphics processing unit (GPU), and/or a modem. For example, the first semiconductor chip may be implemented as a modem die or a modem die supporting a WCDMA (Wideband Code Division Multiple Access) communication method, but is not limited thereto.

The first semiconductor chip 200 may be mounted on the package substrate 100 using a flip chip bonding method. The first chip pads 210 of the first semiconductor chip 200 may be electrically connected to the first substrate pads 110 of the package substrate 100 by the conductive bumps 230, for example, solder bumps.

For example, a thickness of the first semiconductor chip 200 may be within a range of about 40 μm to 110 μm. The first semiconductor chip 200 may have a desired (and/or alternatively predetermined) height from the upper surface 102 of the package substrate 100. The height of the first semiconductor chip 200 may be within a range of about 50 μm to 110 μm.

When viewed from plan view, the first semiconductor chip 200 may be spaced apart from the first dam structure 150a, the second dam structure 150b, and the third dam structure 150c by desired (and/or alternatively predetermined) distances. For example, the spacing distance between the first semiconductor chip 200 and the dam structures may be within in a range of about 100 μm to 500 μm.

In some example embodiments, the second semiconductor chip 300 may be attached to the first semiconductor chip 200 using an adhesive film 320. The third semiconductor chip 300 may be attached to a backside surface of the first semiconductor chip 200 using the adhesive film 320 such as a die attach film DAF by a die attach process. The second semiconductor chip 300 may be disposed such that the backside surface opposite to a front surface on which second chip pads 310 are formed, that is, an inactive surface faces the first semiconductor chip 200. The second semiconductor chip 300 may have a rectangular shape with four sides when viewed from plan view.

For example, a thickness of the second semiconductor chip 300 may be within a range of about 40 μm to 110 μm. A thickness T1 of the adhesive film 320 may be within a range of about 10 μm to 30 μm. The second semiconductor chip 300 may include a memory chip including a memory circuit. For example, the second semiconductor chip may include volatile memory devices such as SRAM devices, DRAM devices, and non-volatile memory devices such as flash memory devices, PRAM devices, MRAM devices, RRAM devices.

In some example embodiments, the second semiconductor chip 300 may be stacked to expose a portion of the upper surface of the first semiconductor chip 200. For example, an area of the second semiconductor chip 300 may be less than an area of the first semiconductor chip 200. An outer surface of the second semiconductor chip 300 and an outer surface of the first semiconductor chip 200 that are adjacent to the first dam structure 150a may be positioned on the same plane. Accordingly, the second semiconductor chip 300 may expose a side portion of the first semiconductor chip 200 adjacent to the first side portion S1 of the package substrate 100.

Alternatively, the second semiconductor chip 300 may be offset-aligned in a horizontal direction on the first semiconductor chip 200. The second semiconductor chip 300 may be offset-aligned in the second direction (X direction) to expose one side portion of the first semiconductor chip 200 adjacent to the first side portion S1 of the package substrate 100.

The second semiconductor chip 300 may be electrically connected to the package substrate 100 using a wire bonding method. The second chip pads 310 of the second semiconductor chip 300 may be electrically connected to the second substrate pads 112 on the upper surface 102 of the package substrate 100 by the second conductive connection members such as the bonding wires 330.

It will be understood that the number, size, arrangement, mounting method, etc. of the first and second semiconductor chips are provided as examples, and the inventive concepts are not limited thereto. Although some first and second chip pads are illustrated in the figures, it should be understood that the structure, shape and arrangement of the first and second chip pads are provided as examples, and the inventive concepts are not limited thereto.

In some example embodiments, the first underfill member 400 may fill the gap between the first semiconductor chip 200 and the package substrate 100. The underfill member 400 may fill the gaps between the conductive bumps 230 between the first semiconductor chip 200 and the package substrate 100. For example, the first underfill member 400 may include a thermosetting resin such as epoxy resin.

The second underfill member 410 may at least partially fill an inner accommodation space of the at least one dam structure. The second underfill members 410 may fill, or in the alternative at least partially fill, the inner spaces of the first dam structure 150a, the second dam structure 150b and the third dam structure 150c. The second underfill member 410 may include a material the same as the first underfill member 400. For example, the second underfill members 410 may fill, or in the alternative at least partially fill, the areas enclosed by the dam structures. For example, the second underfill member 410 may include a thermosetting resin such as epoxy resin.

As illustrated in FIG. 3, the second underfill member 410 may cover one end portion of the bonding wire 330 that is bonded to the second substrate pad 112. The second underfill member 410 may cover a surface of the second substrate pad 112 that is exposed by the end portion of the bonding wire 330.

In some example embodiments, the molding member 500 may cover the first semiconductor chip 200, the second semiconductor chip 300, the first underfill member 400, the second underfill member 410 and the bonding wires 330 on the upper surface 102 of the package substrate 100. The molding member may include a thermosetting resin, for example, epoxy mold compound (EMC). The molding member may be formed through a molding process using a transfer mold.

In some example embodiments, external connection pads (not illustrated) for providing electrical signals may be formed on the lower surface 104 of the package substrate 100. The external connection pads may be exposed by a second insulating layer (not illustrated). The second insulating layer may include a silicon oxide layer, a silicon nitride layer, or a silicon oxynitride layer. External connection members 600 may be disposed on the external connection pads of the package substrate 100 for electrical connection with external devices. For example, the external connection member 600 may be a solder ball. The semiconductor package 10 may be mounted on a module substrate (not illustrated) using the solder balls to form a semiconductor module.

As mentioned above, the semiconductor package 10 may include the at least one dam structure extending on the upper surface 102 of the package substrate 100 to surround the second substrate pads 112, the first semiconductor chip 200 disposed on the package substrate 100, the second semiconductor chip 300 attached to the upper surface 204 of the first semiconductor chip 200 by the adhesive film 320, the bonding wires 330 electrically connecting the second chip pads 310 of the second semiconductor chip 300 to the second substrate pads 112 of the package substrate 100, the first underfill member 400 filling the gaps between the package substrate 100 and the first semiconductor chip 200, the second underfill member 410 filling the receiving (e.g., inner) space of the at least one dam structure that accommodates the second substrate pads 112, and the molding member 500 covering the first semiconductor chip 200, the second semiconductor chip 300 and the first and second underfill members 400 and 410 on the package substrate 100. For example, the at least one dam structure extends to surround the second substrate pads 112 and defines an inner space that accommodates the second substrate pads.

Since the second underfill member 410 covers the end portions of the bonding wires 330 that are bonded to the second substrate pads 112 and covers the surfaces of the second substrate pads 112 exposed by the end portions of the bonding wires 330, when forming the molding member 500 by the molding process using the transfer mold, wire sweeping defects of the bonding wires 330 may be limited or prevented. An additional safety bump (SEC bump) process to improve adhesion of the wire bonding may be omitted, to thereby reduce costs.

Further, since the process of forming the first underfill member 400 is performed after the bonding wire process of the bonding wires 330, the surfaces of the second substrate pads 112 may be limited or prevented from being contaminated by fumes of the underfill solution in the process of forming the first underfill member 400. Accordingly, defects occurring during the wire bonding process due to the contamination of the surface of the bond finger may be limited or prevented.

Hereinafter, a method of manufacturing the semiconductor package of FIG. 1 will be described.

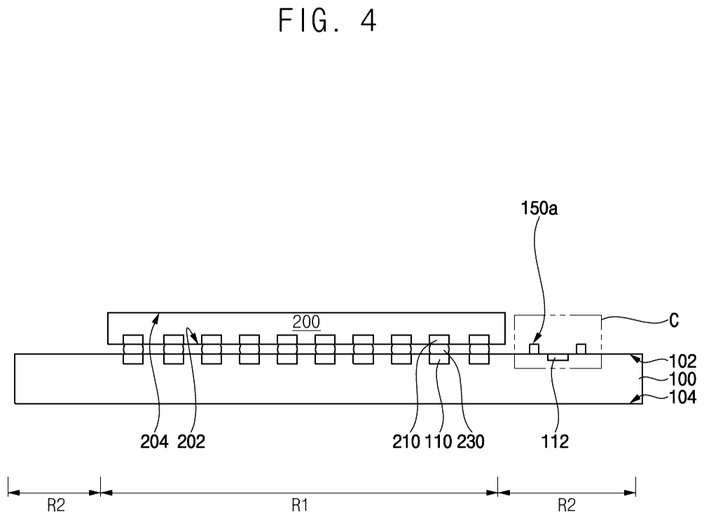

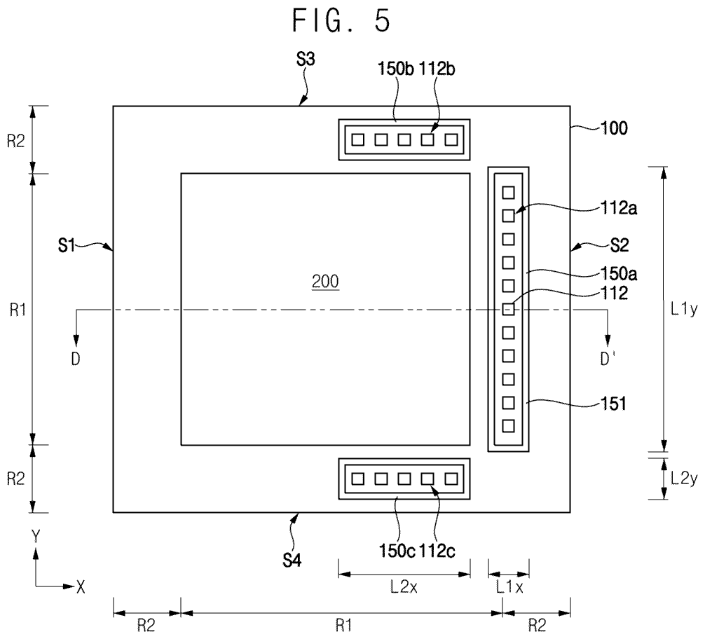

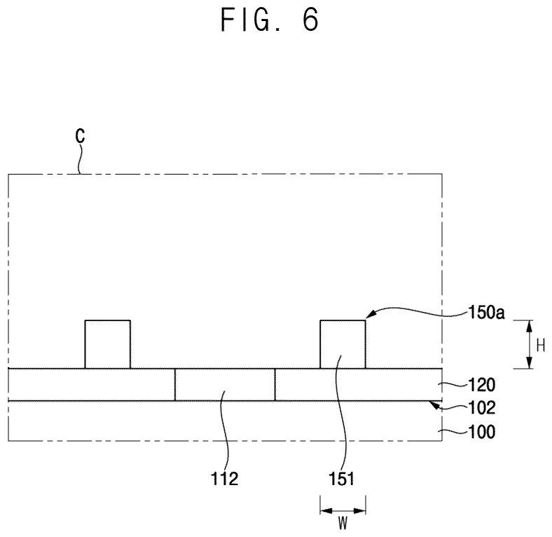

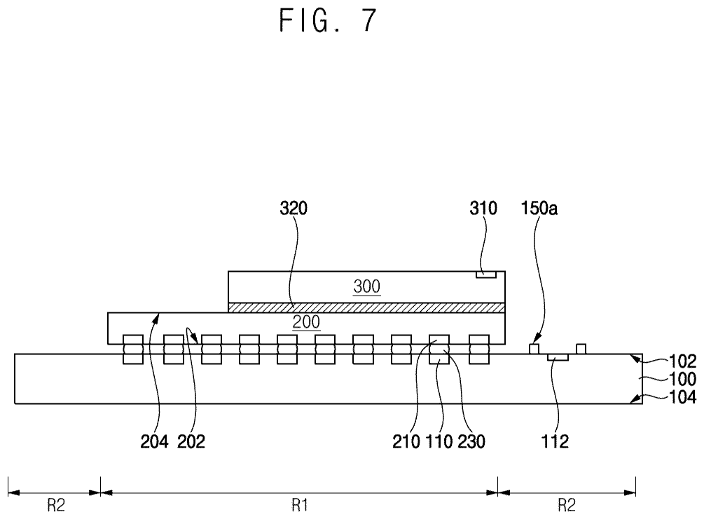

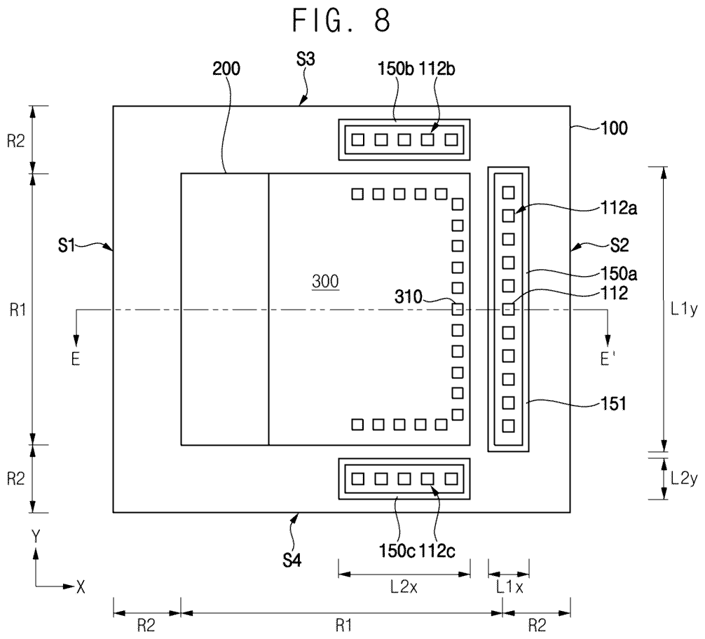

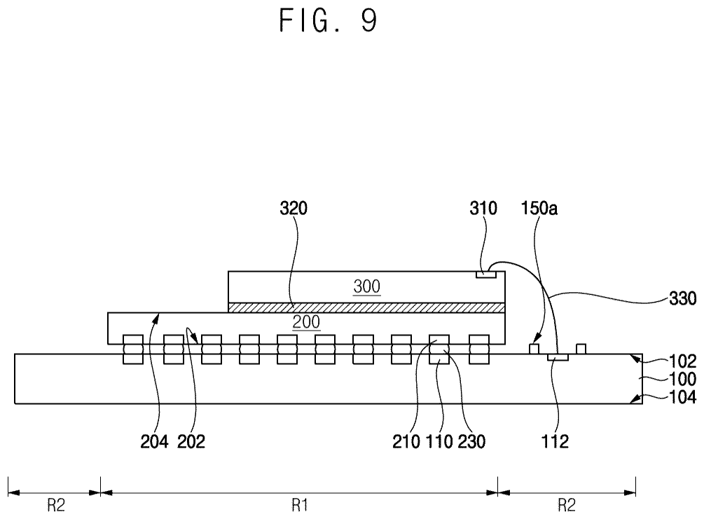

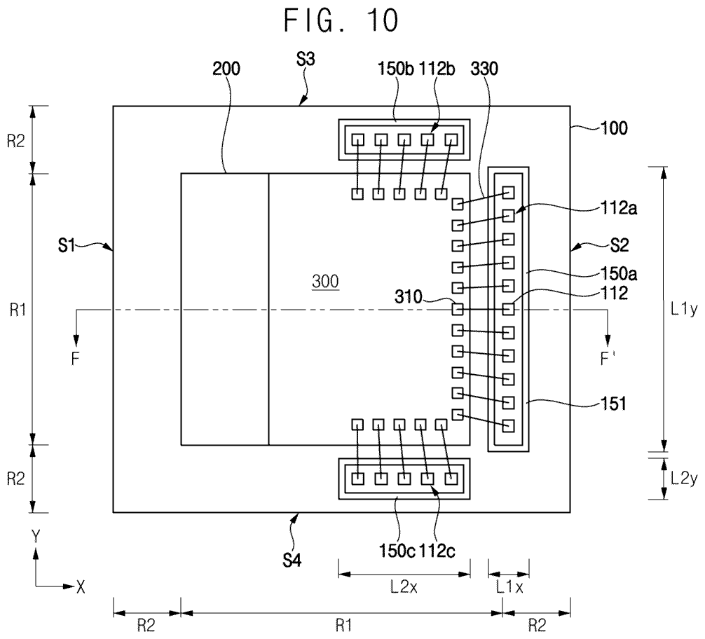

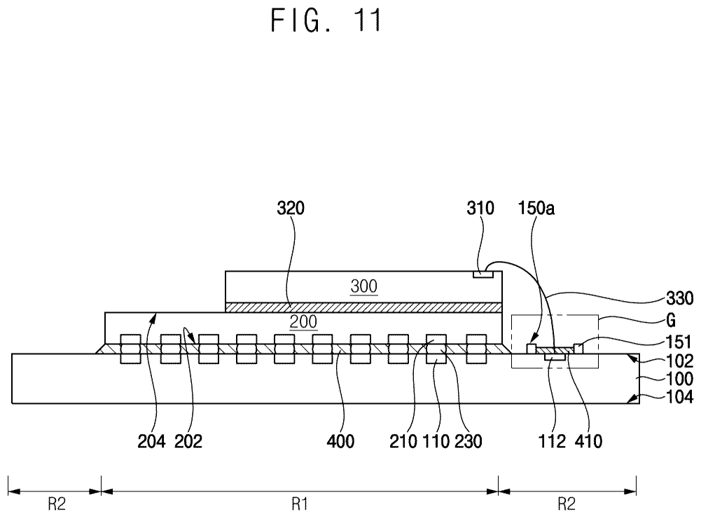

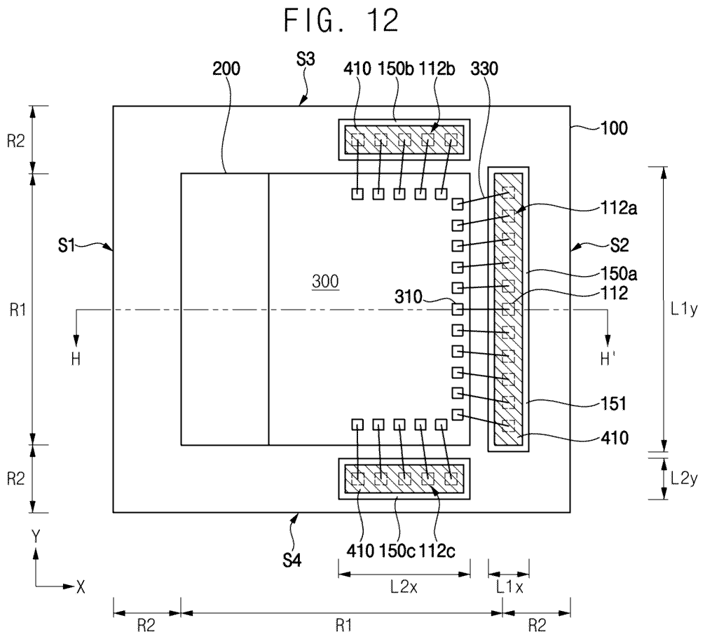

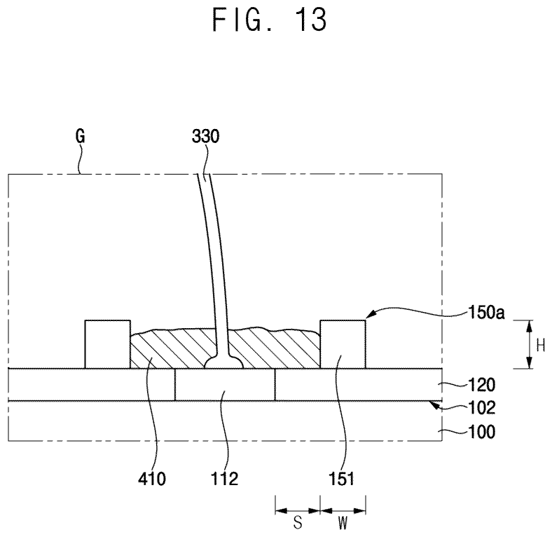

FIGS. 4 to 14 are views illustrating a method of manufacturing a semiconductor package in accordance with some example embodiments of the inventive concepts. FIGS. 4, 7, 9, 11 and 14 are cross-sectional views illustrating a method of manufacturing a semiconductor package in accordance with some example embodiments. FIG. 5 is a plan view of FIG. 4. FIG. 6 is an enlarged cross-sectional view illustrating portion ‘C’ in FIG. 4. FIG. 8 is a plan view of FIG. 7. FIG. 10 is a plan view of FIG. 9. FIG. 12 is a plan view of FIG. 11. FIG. 13 is an enlarged cross-sectional view illustrating portion ‘G’ in FIG. 11. FIG. 4 is a cross-sectional view taken along the line D-D′ in FIG. 5. FIG. 7 is a cross-sectional view taken along the line E-E′ in FIG. 8. FIG. 11 is a cross-sectional view taken along the line H-H′ in FIG. 12.

Referring to FIGS. 4 to 6, a package substrate 100 having first substrate pads 110 and second substrate pads 112 may be provided, and a first semiconductor chip 200 may be mounted on the package substrate 100.

In some example embodiments, the package substrate 100 may be a substrate having an upper surface 102 and a lower surface 104 facing each other. For example, the package substrate 100 may include a printed circuit board (PCB), a flexible substrate, a tape substrate, etc. The package substrate 100 may be a multilayer circuit board having vias and various circuits therein. The package substrate 100 may include internal wirings that serve as channels for electrical connection between the first semiconductor chip 100 and a second semiconductor chip to be mounted thereon.

The package substrate 100 may include a first side portion S1 and a second side portion S2 extending in a direction perpendicular to the upper surface 102 and parallel to a second direction (Y direction) and facing each other. The package substrate 100 may further include a third side portion S3 and a fourth side portion S4 extending in a direction parallel to a first direction (X direction) and perpendicular to the second direction and facing each other.

The package substrate 100 may include a first region R1 and a second region R2 surrounding the first region R1. The first region R1 may be a chip mounting region on which the first semiconductor chip 200 and the second semiconductor chip are mounted. The second region R2 may be a peripheral region surrounding the chip mounting region. The first region R1 may have a rectangular shape.

The first substrate pads 110 may be provided in the first region R1 on the upper surface 102 of the package substrate 100 and may be electrically connected to the first semiconductor chip 200. The first substrate pads 110 may be arranged in an array form within the first region R1. The second substrate pads 112 may be provided in second region R2 on the upper surface 102 of the package substrate 100 and may be electrically connected to the second semiconductor chip.

The second substrate pads 112 may be arranged to be spaced apart from each other along the second, third and fourth side portions S2, S3 and S4. The second substrate pads 112 may include a first group of pads 112a arranged along the second side portion S2 of the package substrate 100, a second group of pads 112b arranged along the third side portion S3 of the package substrate 100, and a third group of pads 112c arranged along the fourth side portion S4 of the package substrate 100.

The first and second substrate pads 110 and 112 may be respectively connected to the wirings (e.g., the internal wirings of the package substrate 100). The wirings may extend on the upper surface 102 or inside the package substrate 100. For example, at least a portion of the wiring may be used as a landing pad or as a substrate pad.

Although only some substrate pads are illustrated in the figures, it will be understood that the number, shape, and arrangement of the substrate pads are provided as examples, and the inventive concepts are not limited thereto. Further description and illustration of the wirings as well as the substrate pads to which the inventive concepts pertain will be omitted from the following.

A first insulating layer 120 may be formed on the upper surface 102 of the package substrate 100 to expose the first and second substrate pads 110 and 112. The first insulating layer 120 may cover the entire upper surface 102 of the package substrate 100 excluding the first and second substrate pads 110 and 112. For example, the first insulating layer may include solder resist.

In some example embodiments, at least one dam structure may be provided in the second region R2 on the upper surface 102 of the package substrate 100 to surround the second substrate pads 112. The dam structure may protrude from the upper surface 102 of the package substrate 110 to have a desired (and/or alternatively predetermined) height H. The dam structure may include a barrier 151 that extends to surround the second substrate pads 112.

For example, the barrier 151 of the dam structure may be formed by forming a protective layer such as a solder resist on the first insulating layer 120 and performing an exposure process and a development process on the protective layer.

As illustrated in FIG. 6, the height H of the barrier 151 of the at least one dam structure may be within a range of about 10 μm to 30 μm. A width W of the barrier 151 of the at least one dam structure may be within a range of about 100 μm to 200 μm. A gap S between an inner wall of the barrier 151 of the at least one dam structure and the second substrate pad 112 (e.g., see FIG. 3) may be within a range of about 100 μm to 250 μm.

The at least one dam structure may include a first dam structure 150a surrounding the first group of pads 112a, a second dam structure 150b surrounding the second group of pads 112b, and a third dam structure 150c surrounding the third group of pads 112c. A length L1x of the first dam structure 150a in the first direction (X direction) may be within a range of about 100 μm to 250 μm, and a length L1y of the first dam structure 150a in the second direction (Y direction) may be within a range of about 4,000 μm to 5,000 μm. A length L2x of the third dam structure 150c in the first direction (X direction) may be within a range of about 2,000 μm to 3,000 μm, and a length L2y of the third dam structure 150c in the second direction (Y direction) may be within a range of about 200 μm to 300 μm.

In some example embodiments, the first semiconductor chip 200 may be mounted in the first region R1 of the package substrate 100. The first semiconductor chip 200 may be mounted in the first region R1 on the upper surface 102 of the package substrate 100 via conductive bumps 230. The first semiconductor chip 200 may be disposed such that a front surface 202 on which first chip pads 210 are formed, that is, an active surface, faces the package substrate 100. The first semiconductor chip 200 may have a rectangular shape with four sides when viewed from plan view. The first chip pads 210 may be arranged in an array over the entire front surface 202 of the first semiconductor chip 200 corresponding to the first substrate pads 110.

The first semiconductor chip 200 may be a logic chip including a logic circuit. The logic chip may be a controller that controls memory chips. The first semiconductor chip may be a processor chip such as ASIC, an application processor AP, etc. serving as a host such as a CPU, GPU, or SOC. The first semiconductor chip may include a central processing unit CPU, a graphics processing unit GPU, and/or a modem. For example, the first semiconductor chip may be implemented as a modem die or a modem die supporting a WCDMA (Wideband Code Division Multiple Access) communication method, but is not limited thereto.

The first semiconductor chip 200 may be mounted on the package substrate 100 using a flip chip bonding method. The first chip pads 210 of the first semiconductor chip 200 may be electrically connected to the first substrate pads 110 of the package substrate 100 by the conductive bumps 230, for example, solder bumps.

For example, a thickness of the first semiconductor chip 200 may be within a range of about 40 μm to 110 μm. The first semiconductor chip 200 may have a desired (and/or alternatively predetermined) height from the upper surface 102 of the package substrate 100. The height of the first semiconductor chip 200 may be within a range of about 50 μm to 110 μm.

When viewed from plan view, the first semiconductor chip 200 may be spaced apart from the first dam structure 150a, the second dam structure 150b, and the third dam structure 150c by desired (and/or alternatively predetermined) distances. For example, the spacing distance between the first semiconductor chip 200 and the dam structures may be within in a range of about 100 μm to 500 μm.

Referring to FIGS. 7 and 8, a second semiconductor chip 300 may be attached to the first semiconductor chip 200 using an adhesive film 320. The third semiconductor chip 300 may be attached to a backside surface of the first semiconductor chip 200 using the adhesive film 320 such as a die attach film DAF by a die attach process. The second semiconductor chip 300 may be disposed such that the backside surface opposite to a front surface on which second chip pads 310 are formed, that is, an inactive surface faces the first semiconductor chip 200. The second semiconductor chip 300 may have a rectangular shape with four sides when viewed from plan view.

For example, a thickness of the second semiconductor chip 300 may be within a range of about 40 μm to 110 μm. A thickness T1 of the adhesive film 320 may be within a range of about 10 μm to 30 μm. The second semiconductor chip 300 may include a memory chip including a memory circuit. For example, the second semiconductor chip may include volatile memory devices such as SRAM devices, DRAM devices, and non-volatile memory devices such as flash memory devices, PRAM devices, MRAM devices, RRAM devices.

In some example embodiments, the second semiconductor chip 300 may be stacked to expose a portion of the upper surface of the first semiconductor chip 200. For example, an area of the second semiconductor chip 300 may be less than an area of the first semiconductor chip 200. An outer surface of the second semiconductor chip 300 and an outer surface of the first semiconductor chip 200 that are adjacent to the first dam structure 150a may be positioned on the same plane. Accordingly, the second semiconductor chip 300 may expose a side portion of the first semiconductor chip 200 adjacent to the first side portion S1 of the package substrate 100.

Alternatively, the second semiconductor chip 300 may be offset-aligned in a horizontal direction on the first semiconductor chip 200. The second semiconductor chip 300 may be offset-aligned in the second direction (X direction) to expose one side portion of the first semiconductor chip 200 adjacent to the first side portion S1 of the package substrate 100.

Referring to FIGS. 9 and 10, the second semiconductor chip 300 may be electrically connected to the package substrate 100 through conductive connection members 330.

In some example embodiments, a wire bonding process may be performed to connect the second chip pads 310 of the second semiconductor chip 300 to the second substrate pads 112 on the upper surface 102 of the package substrate 100 using bonding wires 330.

Referring to FIGS. 11 to 13, a first underfill member 400 may be formed between the first semiconductor chip 200 and the package substrate 100 and a second underfill member 410 may be formed to fill an inner accommodation space of the at least one dam structure.

In some example embodiments, a dispenser nozzle may dispense an underfill aqueous solution (UFL) while moving in the second direction (Y direction) between the first semiconductor chip 200 and the package substrate 100. For example, the aqueous underfill solution may include an epoxy material. The underfill aqueous solution may flow between the first surface 202 of the first semiconductor chip 200 and the upper surface 102 of the package substrate 100, and then, may be cured to form the first underfill member 400.

Before or after forming the first underfill member 400, the dispenser nozzle may dispense an underfill aqueous solution (UFL) into the inner spaces of the first dam structure 150a, the second dam structure 150b and the third dam structure 150c. For example, the aqueous underfill solution may include an epoxy material. The underfill aqueous solution may flow through the insides of the first dam structure 150a, the second dam structure 150b, and the third dam structure 150c, and then, may be cured to form the second underfill members 410 respectively.

As illustrated in FIG. 13, the second underfill member 410 may cover one end portion of the bonding wire 330 that is bonded to the second substrate pad 112. The second underfill member 410 may cover a surface of the second substrate pad 112 that is exposed by the end portion of the bonding wire 330.

Since the process of forming the first underfill member 400 is performed after the bonding wire process of the bonding wires 330, the surfaces of the second substrate pads 112 may be limited or prevented from being contaminated by fumes of the underfill solution in the process of forming the first underfill member 400. Accordingly, defects occurring during the wire bonding process due to the contamination of the surface of the bond finger may be limited or prevented.

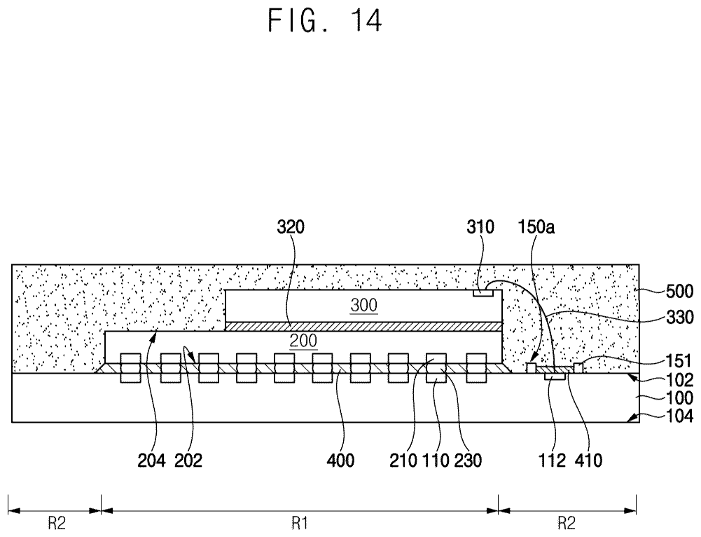

Referring to FIG. 14, a molding member 500 may be formed on the upper surface 102 of the package substrate 100 to cover the first and second semiconductor chips 200 and 300 and the first and second underfill members 400 and 410.

In some example embodiments, the molding member 500 may be formed through a molding process using a transfer mold. For example, the molding member 500 may include epoxy mold compound (EMC).

Since the second underfill member 410 covers the end portions of the bonding wires 330 that are bonded to the second substrate pads 112 and the surfaces of the second substrate pads 112 exposed by the end portions of the bonding wires 330, when forming the molding member 500 through the molding process using the transfer mold, wire sweeping defects of the bonding wires 330 may be limited or prevented. Further, an additional safety bump (SEC bump) process to improve adhesion of the wire bonding may be omitted, to thereby reduce costs.

Then, external connection members may be formed on external connection pads (not illustrated) on the lower surface 104 of the package substrate 100 to complete a semiconductor package 10 of FIG. 1.

For example, the external connection members may include solder balls. The external connection members may be respectively formed on the external connection pads on the lower surface 104 of the package substrate 100 through a solder ball attach process.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although some example embodiments have been described, those skilled in the art will readily appreciate that many modifications are possible in example embodiments without materially departing from the novel teachings and advantages of the inventive concepts. Accordingly, all such modifications are intended to be included within the scope of example embodiments as defined in the claims.

What is claimed is:

1. A semiconductor package, comprising:
a package substrate having an upper surface and a lower surface opposite the upper surface, the package substrate including a first region and a second region surrounding the first region, the package substrate including first substrate pads on the upper surface in the first region and second substrate pads on the upper surface in the second region;
at least one dam structure protruding from the upper surface of the package substrate and having a first height from the upper surface of the package substrate, the at least one dam structure extending to surround the second substrate pads and defining an inner space that accommodates the second substrate pads on the package substrate;
a first semiconductor chip in the first region on the package substrate, the first semiconductor chip having a first surface with first chip pads thereon, the first surface facing the package substrate;
a second semiconductor chip attached to a second surface of the first semiconductor chip opposite to the first surface by an adhesive film, the second semiconductor chip having a third surface and a fourth surface opposite to a third surface, the fourth surface having second chip pads thereon, and the third surface facing the first semiconductor chip;
bonding wires electrically connecting the second chip pads of the second semiconductor chip to the second substrate pads of the package substrate;
a first underfill member filling a gap between the first semiconductor chip and the upper surface of the package substrate;
a second underfill member at least partially filling the inner space of the at least one dam structure; and
a molding member covering the first semiconductor chip, the second semiconductor chip, and the first and second underfill members on the package substrate.

2. The semiconductor package of claim 1, wherein the second substrate pads include a first group of pads along a first side portion of the package substrate that extends in a direction perpendicular to the upper surface of the package substrate and parallel to a first direction, and a second group of pads along a second side portion of the package substrate that is adjacent to the first side portion and extends in a direction parallel to a second direction perpendicular to the first direction, and
The at least one dam structure includes a first dam structure surrounding the first group of pads and a second dam structure surrounding the second group of pads.

3. The semiconductor package of claim 1, wherein the first height of the at least one dam structure is within a range of 10 μm to 30 μm.

4. The semiconductor package of claim 1, wherein a width of the at least one dam structure is within a range of 100 μm to 200 μm.

5. The semiconductor package of claim 1, wherein a distance between an inner wall of the at least one dam structure and the second substrate pads is within a range of 100 μm to 250 μm.

6. The semiconductor package of claim 1, wherein the second underfill member covers one end portion of a bonding wire from among the bonding wires that is bonded to a second substrate pad from among the second substrate pads.

7. The semiconductor package of claim 1, wherein the first underfill member and the second underfill member include a same material.

8. The semiconductor package of claim 7, wherein the first and second underfill members include an epoxy material.

9. The semiconductor package of claim 1, wherein the adhesive film includes a die attach film.

10. The semiconductor package of claim 1, wherein the first semiconductor chip is mounted on the first substrate pads via conductive bumps that are on the first chip pads.

11. A semiconductor package, comprising:
a package substrate including a first region and a second region surrounding the first region, the package substrate having first substrate pads in the first region and second substrate pads in the second region along at least one side portion of the package substrate;
at least one dam structure extending to surround the second substrate pads on an upper surface of the package substrate and defining an inner space that accommodates the second substrate pads on the upper surface of the package substrate;
a first semiconductor chip in the first region of the package substrate and mounted on the first substrate pads via conductive bumps that are on first chip pads of the first semiconductor chip;
a second semiconductor chip on the first semiconductor chip, the second semiconductor chip having a backside surface and a front surface opposite the backside surface, the front surface having second chip pads thereon, and the backside surface faces the first semiconductor chip;
bonding wires electrically connecting the second chip pads of the second semiconductor chip to the second substrate pads of the package substrate;
a first underfill member filling a gap between the first semiconductor chip and the package substrate;
a second underfill member filling the inner space of the at least one dam structure, the second underfill member provided on the second substrate pads; and
a molding member covering the first semiconductor chip, the second semiconductor chip, and the first and second underfill members on the package substrate.

12. The semiconductor package of claim 11, wherein the first chip pads are on a first surface of the first semiconductor chip, and the first surface faces the package substrate.

13. The semiconductor package of claim 11, wherein the second semiconductor chip is attached to an upper surface of the first semiconductor chip by an adhesive film and exposes a portion of the upper surface of the first semiconductor chip.

14. The semiconductor package of claim 13, wherein the adhesive film includes a die attach film.

15. The semiconductor package of claim 11, wherein a height of the at least one dam structure from the package substrate is within a range of 10 μm to 30 μm.

16. The semiconductor package of claim 11, wherein a width of the at least one dam structure is within a range of 100 μm to 200 μm.

17. The semiconductor package of claim 11, wherein a gap between an inner wall of the at least one dam structure and the second substrate pads is within a range of 100 μm to 250 μm.

18. The semiconductor package of claim 11, wherein the second underfill member covers one end portion of a bonding wire from among the bonding wires that is bonded to a second substrate pad from among the second substrate pads.

19. The semiconductor package of claim 11, wherein the first underfill member and the second underfill member include a same material.

20. A semiconductor package, comprising:
a package substrate including a first region and a second region surrounding the first region, the package substrate having first substrate pads in the first region and second substrate pads in the second region along at least one side portion of the package substrate;
at least one dam structure protruding from an upper surface of the package substrate to having a first height from the package substrate, the at least one dam structure extending to surround the second substrate pads and defining an inner space that accommodates the second substrate pads on the package substrate;
a first semiconductor chip in the first region of the package substrate, the first semiconductor chip having a first surface with first chip pads thereon, the first surface facing the package substrate, the first semiconductor chip mounted on the first substrate pads via conductive bumps on the first chip pads;
a second semiconductor chip on a second surface of the first semiconductor chip opposite to the first surface by an adhesive film, the second semiconductor chip exposing a portion of the second surface of the first semiconductor chip, the second semiconductor chip having a fourth surface opposite to a third surface, the fourth surface having second chip pads thereon, and the third surface facing the first semiconductor chip;
bonding wires electrically connecting the second chip pads of the second semiconductor chip to the second substrate pads of the package substrate;
a first underfill member filling a gap between the first semiconductor chip and the package substrate;
a second underfill member filling the inner space of the at least one dam structure and on the second substrate pads; and
a molding member covering the first semiconductor chip, the second semiconductor chip, and the first and second underfill members on the package substrate,
wherein the first height of the at least one dam structure is within a range of 10 μm to 30 μm.
